(19) United States
(12) Patent Application Publication
(10) Pub. No.: US 2006/0117242 A1
(43) Pub. Date: Jun. 1, 2006

(54) Methods and devices for defect and reallocation management on write-once media

(76) Inventors: Dirk Hamelinck, Eindhoven (NL); Pope Ijtsma, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/528,945

(22) PCT Filed: Sep. 29, 2003
(86) PCT No.: PCT/IB03/04240

§ 371 Date: Mar. 23, 2005

(30) Foreign Application Priority Data
Sep. 27, 2002 (EP) 020790689

(51) Int. Cl. G11C 29/00

(52) U.S. Cl. 714/763

(57) ABSTRACT

The invention relates to a method and a device for random write and overwrite to a write once recordable medium, a method and a device for defect management on a write once recordable medium, a method and a device for undo changes made to a write once recordable medium, and a method and a device for reuse of a used write once recordable medium.

As a result of the different physical properties of write once media in comparison with rewritable media, the use and application models used for both types of media has historically developed differently. The key advantage of rewritable media is its ability to effectively carry changing data, where write-once media has as a key advantage its ability to store data almost forever without the risk of loosing this data later by erroneous user actions (such as unintentional overwrite and delete actions).

The differences between these types of media can be mainly found in the following areas:

1. sequential write versus random write Write once media has until now typically been used for sequential storage (where data is appended to previous data), where rewritable media has also been able to support random storage next to its ability to support sequential storage. Examples of sequential storage, used for example in CD-R, are: “track-at-once”, “disk at once”, and “multi-session” or “drag-and-drop” writing. The same can be done with rewritable media, such as for example CD-RW and DVD+RW. But additionally “random drag-and-drop” writing of data and other random writing strategies can be done with these rewritable media.

2. store for ever versus changing content and reuse of media Write once media has the advantage that any written data can always be restored (as long as no physical overwrites is done, or no damage is done to the physical media itself). As a result, write once media has established itself mainly in application area's where the information does not need to be updated later (like, for example, a personal copy of a CD), or when it is highly desirable never to loose the data due to user-mistakes (like archiving). Rewritable media is mainly used in applications where it is expected that the stored content will need updates later on, or where there is no need to be kept for a long time. Rewritable media are used as well for temporary storage, both in case of sequential recording (record disk or track, but allow blanking and re-use of the media in the future) and of random storage (drag an drop, backups, etc).

3. knowledge in host system about media-storage functions In general, it is not desirable that the host system (for example, a personal computer or a stand-alone consumer DVD-recorder) needs to know a lot of specifics about the characteristics of the media-carrier, as this only complicates the application design, increases the amount and detail of the drive to host communication, and limits the applicability of these media to their specific uses and applications. An example of this is the abundance of different solutions for current write once media, such as CD-R, specially designed to overcome the aspect of such limitations (TAO, DAO, RAW-mode, Q-sheet, multi-session, fixed and random packet-writing, etc.). Another example is the extra complexity at application level. The operating system UDF1.5 was specially developed for it's ability to deal with defective media (defect-management in file systems) and it's capability to change already written data and file-structures on CD-R (reallocation of sectors by the file-system). As a comparison, rewritable media such as CD-MRW and DVD+MRW, enable 2 k random (read and write) addressing in a one session format, including background formatting, caching and defect-management performed by the drive, without any need for very specific media knowledge at the host.

It is an object of the present invention to provide methods of working with write once media such that the key-advantages of random-rewritability (such as, for example, changeable content, random addressing, low media knowledge needed at the host, reuse of media) can be combined with the key advantage of write once media (i.e., permanent storage). This object should preferably be achieved without blocking any of the specific application-designs available today and expected in the future. Furthermore, it is desirable that a host system or an application need not worry about sequentially of written data, as this only adds system design complexity and limitations to functionality.

It is a further object of the present invention to provide a device, such as for example a disc drive, capable of carrying out a method according to the invention.

The above objects are achieved by providing
a method and a device for random write and overwrite to a write once recordable medium,
a method and a device for defect management on a write once recordable medium,
a method and a device for undo changes made to a write once recordable medium, and
a method and a device for reuse of a used write once recordable medium.

It is noted that in a preferred embodiment the device is a disc drive. It is further noted that in a preferred embodiment the method is implemented in the disc drive instead of in the host system.

It is also noted that the methods and devices according to the invention can be especially advantageously, but not exclusively, applied in optical recording systems according to the Blu-Ray Disc standard. This because this system evolves from a rewritable implementation to a write once implementation, in contrast to, for example, systems according to the CD and DVD standards which evolve from a read-only implementation to a rewritable implementation.

The objects, features and advantages of the invention will be apparent from the following more particular description of embodiments of the invention. Furthermore, the essence of the invention is illustrated in the accompanying drawings 1 to 5.

In the embodiments described further on, reference will be made to a non-limiting example of a typical write once disk existing out of 3 types of area's:
Boundary Areas (BA), typically called LEAD-IN at the begin and LEAD-OUT at the end of a disk, used for disk-type and content-organization recognition, use characterization (like, for example, write strategies or data protection mechanisms), and any other purposed storage of data;
A User-Area (IA), where all user data needs to be contained in (file-systems and user files being key examples);
An Administrative Area (AA), containing other than normal user data as stored in the UA. This data is needed internally for the housekeeping of the drive or the host to full-fill all user-functions. Examples of data in the AA are the replacement tables or the sparing data from the original user-locations in the UA.

For simplicity purposes, without trying to limit the applicability of the invention to more complex disks layouts, we will assume each of these areas to exist out of one contiguous space, each linearly addressed (BA: −Y . . . −1, UA: 0 . . . N, AA: M . . . Z), without addressing interruptions, as shown below:

| | | | | | |
|---|---|---|---|---|---|
| −Y | −1 | 0 | N | M | Z |
| BA | | UA | | AA | |

Obviously, other arrangements are also valid, even in case of a non-contiguous, mixed, and non-linear arrangement of the areas of which a non-limiting example is shown below:

| | | | | | | | | | |
|---|---|---|---|---|---|---|---|---|---|
| −1 | −Y | 0 | G | P | K | L | Z | H | J |
| BA | | UA | | AA | | UA | | BA | |

Most write once disks have a fixed “minimal write block size”. Here we will call this the BLOCK-SIZE. In such case writing less data is not possible without at least physically writing a fall block of data having the BLOCK-SIZE, thus requiring the drive, or host, to fill in the lacking amount of data. Furthermore, a typical host system has a minimal data-size it will send to or ask from a drive. We will call this minimal data-size the ADRESSING-SIZE. In the process of receiving or sending data from or to the host, a typical drive is able to group the data into a single data-stream, which process is called caching.

The above terminology is for sake of clarification of the invention, and can not be considered as limiting. Many other types or variations of disk-structures, and drive and host behavior are alternatively possible.

Furthermore, although the functionality of the inventions is described for write once media, all the techniques are also applicable for ROM-media and for rewritable media used in a write once way. ROM-media is like write once media which is completely written, and which has no free capacity available. Rewritable media can be considered write once media when the physical locations are not overwritten.

Next, embodiments of a method and a device for random write and overwrite to a write once recordable medium according to the invention will be described.

Typically, write once solutions are designed for writing sequentially to the UA. In such case, the addresses in the UA are written beginning with the lowest logical or physical address, and successive data is appended to the tail of the previously written data. In some cases exceptions can be made to this by the creation of “multiple open sessions”. However, in such cases these sessions are typically administrated as separate UA's, with identical sequential writing condition within each individual session. Alternatively, it is possible that in write once use the data is not written sequentially, but that the host may administrate the required housekeeping of the “area's still free” and the “written area's” to assure no data is accidentally overwritten.

In this embodiment of the invention, we will make no assumptions nor rules on places and sequences which the host needs to known when sending data to the drive to be stored. Therefore, this embodiment is designed such that at any time, any position to where the host requests a write to the UA, the drive will store the data on the disk on the by the host designated location. This is handled by the drive in following steps:
1. Cache the data send by the host, potentially sent in non sequential clusters of multiples of the host addressing-size, to fit a multiple of the disk BLOCK SIZE;
2. If the data-stream is not fitting the needed multiple of the BLOCK SIZE, or addressing of the data send does not fit the borders of the physical/logical blocks as defined in the UA, the drive will
   2.1. fill in dummy data to complete the block in case this is data for free area (see 3),
   2.2. or collect data of the missing parts of the data-BLOCK(s) disk by reading this data from disk and filling it in the correct location of the data-stream;
3. The drive will check, without needed interaction the host, if the requested storing locations as still unwritten (that is, free);
4. For this purpose, the drive will administrate in the AA at occupied-area-table, which will be kept updated in memory, and a form of it stored on the disc when needed (e.g., eject or flushing the cache);
5. For the parts of the data with match free blocks, the drive will write the data to the correct free locations of the disk, directly or delayed by buffering;
6. When part of the data-locations is already occupied, the drive will store that data in free space of the AA, reserved for that purpose (called SPARE AREA), and update a table in memory and when needed on disk (e.g., eject or flush cache) for designating the logical location of the UA to be mapped to a new physical location in the AA;
7. As a result, the content of any logical address on the write once disk can be updated, as long as free space in the AA is available for this purpose;
8. When the free area in AA is draining, the drive will signal this to the host by acknowledging a “reaching end of free overwrite capacity”, as a result of host-polling mechanism or a drive “event-generation mechanism”.

As a result, as long as the host sees free logical UA space available for new write actions and knows there is free AA space for sparing any overwrites (due to a host choice or an internal drive actions), the host does not need to be bothered with the knowledge about how the data is stored physically on the disk. Furthermore, the host may consciously update logical locations, just as a host would do in case of a rewritable medium. The only trade-off is the need for the drive to administrate the replacement position, and update the related replacement table which will allow to reconstruct the relation logical address as designated by the host, and the physical address where the data is stored. This operation is done with a minimal need of knowledge in the host, resulting in random addressing by the drive on write once media.

The factor left in this way of working is the reserved space needed of the AA for storing the overwritten area's. It would be needing to predict how much AA area will be needed in future use of the medium. This is a restriction which is not desirable, as the user or application needs cannot be predicted in advance and may vary strongly. Reserving AA space comes automatically at cost of UA space when having a limited medium storage capacity. As a result, the storage capacity would be reduced excessively because, when anticipating the expected behavior, sometimes to much will have been reserved (running out of spare area in AA) or sometimes to much has been reserved (running out of UA).

In an embodiment of the invention this issue is solved by making the split between the UA and AA dynamic, thus allowing the drive to allocate and rearrange UA and AA addresses as needed by host or drive. Physical addresses not written to by the host will be considered “free for future use as UA or AA” and addresses occupied due to writing by the host or the drive will have found their classification as UA or AA area. When reading addresses by the host of locations which have no designation yet, the drive will respond with “dummy data” (such as for example a “bbbb . . . ” pattern filled in over the whole undesignated area).

This embodiment has the advantage that the host can send data to the drive, while the UA and AA area can be used optimally for fitting these request of the host until there is no free unwritten space left any more in UA and AA. In this way the maximal storage capacity will be fully used. The same mechanism of communication as described above (polling or event generation) can be used for assuring that the host will not send more data to the drive than the drive can store. In invent of an unforeseen overflow case, the drive will send an error condition to the host, thus signaling the need for terminating the data write-process by the host.

Next, embodiments of a method and a device for defect management on a write once recordable medium according to the invention will be described. The same mechanism as described above can also be used for defect management purposes.

On other media, typically two mechanisms of defect management are used:
linear sparing: where in one logical address of the UA is reallocated to free positions in the AA. The logical order in the rest of the UA is kept as before making this linear spare; one section of the UA is remapped to the AA;
slipping: where in one part of the UA is taken out of the UA. A lot of the logical addresses of the rest of the UA may need to be adapted (in most cases the addresses greater then the slipped addresses), as a mismatch is made between physical an logical order by taking out a range of addresses in the UA.

For most systems using defect management, defect tables are kept in tables, and in most cases such tables are not mixed into each other but separately stored and updated. Furthermore, most systems only use defect management for rewritable media, and limit the use of slipping to the media formatting phase, instead of using linear replacement and slipping dynamically, during the active data-storage phase of the life of the medium.

In an embodiment of the current invention, formatting for defect-detection prior to writing may run the background, whilst data might be stored during the same activity. The defect detection and sparing decisions can be a result of formatting activities, or defect detection during write, or defect detection during read after write, or for whatever reason at whatever moment.

In case of write once, as writing consumes free-space, except for organizing required disk structures in the BA and AA, it is desired to do background formatting without writing (by, for example, dummy writes or reads) of any special action by finding defects prior to needing to write to the selected location. Also, it might be desirable to actively write and read to UA's without a specific request of the host in order to improve detection ability of the drive. Defect management can then alternatively be used to make sure that the data send to the host to the same logical location, is replaced to another location in the AA or other locations in the UA dynamically reassigned to be used as AA.

In an embodiment of the invention it is chosen not to restrict the use of linear sparing, slipping and defect management prior to formatting, during foreground formatting, during background formatting, during active read/write phase, during idle phase or any phase when the disk is inserted into the drive.

As an example, a combination of slipping and linear replacement dynamically, together with dynamic redefinition of the UA and the AA, may have specific advantages in the case of streaming data types. Typically, physical and logical organization of the write once media may cause linear replacement to be the most optimal sparing method from capacity viewpoint. However, sometimes the location of the related spares may cause strong decrease of the streaming performance. By caching the data for defect locations in the drive (or on the disk, and sparing also these buffer addresses) and then writing them as a single stream to a free contiguous area in the UA close to the original defect-addresses, and then slipping these used UA addresses and reassigning them as AA, future streaming read-performance of this content or part of the content will have improved significantly.

In such a solution, more performance and easier design may be established by combining or separating the reallocation tables or parts of these lists, as caused by random addressing, overwriting, linear sparing and slipping. In the solution as disclosed here, it is preferred that the drive decides by itself, self learning over lifetime, be instructed by the host, or any other means, and that the information contained in UA, DA or AA on the disc will be sufficient for understanding the selected method for defect management administration and random/write or overwrite administration.

Next, embodiments of a method and a device for undo changes made to a write once recordable medium according to the invention will be described.

At any time critical to the UA, AA or BA data of the disk (for example, after caching, before eject or power down, or any state of the drive, the disk, or the host to cause such update), all relevant information to restore the state and the logical content of the user-data and the disk, administration data is written on the disk. As the medium is a write once medium, and the system may on top of this even be build such that accidental overwrite or loss of data is virtually impossible, it is to construct the administration tables on the disk such that the drive can go back to a previous state of these tables, including access to all related correct data fitting to that state, or move to a next state (already recorded to the disk). This can be initiated or executed by the drive itself, by the host, by a user intervention, or by any circumstance motivating such action.

Furthermore, it is possible to start from a previous state of the disk, and resume active data interchange with the host or with internal processes to the drive, as if this state was the last state of the disk. Thus allowing an easy way to “go x steps back or forward”, and to continue from that point as was this the last state of the disk.

According to an embodiment of the invention, this is organized by adding multiple forward and backward location pointers in the structures or information as stored in the BA, UA or AA, such that navigating backwards and forward through the storing state as performed over time is possible.

According to an embodiment of the invention, this functionality is used for specific applications like retrieving and restoring data-backups of previous recorded data back in time, changes delta verifications, data-sync functionality, or just correcting for user, host or drive intentional or unintentional data storing or changes to the disk.

Next, embodiments of a method and a device for reuse of a used write once recordable medium according to the invention will be described.

Most write once media are used for a one-time purpose and than thrown away after the useful period of the data on the disk for the user is passed.

According to an embodiment of the present invention using the same mechanism as described above, when any free space is still available on the disk, it is possible to logically reformat the disk and obtaining the free capacity of the disk as if it was a new disk, but now with smaller available capacity due to the previous usage of space of the disk. This leads to the same reuse possibility as an user would re-use a normal rewritable medium, but now with a write once medium. Now, up to the very last free bits of the disk can be used as new disk-storage space.

In an embodiment which combines the “reuse” functionality with the “undo changes” functionality, it is possible to create multiple partitions which can coexist, hide data from each other, and allow the host, the drive, or the user to move data from one partition to another on a write once disk.

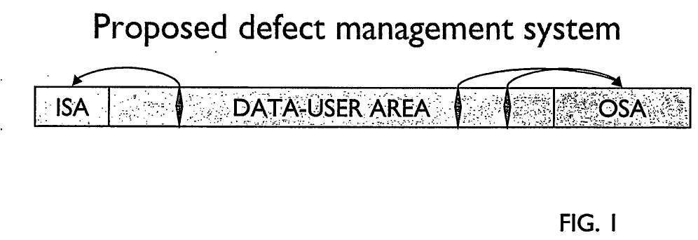

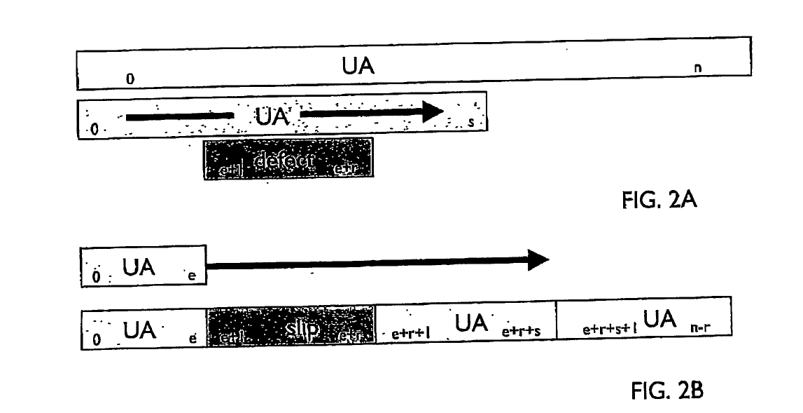

In FIG. 2 an example of a defect management system according to the invention for writing on a blank disc is illustrated. As is shown in FIG. 2A there is a large defect on e+1 till e+r. The solution as shown in FIG. 2B is to apply slipping and to take the original defect area e+1 till e+r out of the User-Area (UA). This decreases the free capacity of the UA with a size “r′” which is occupied by the defect.

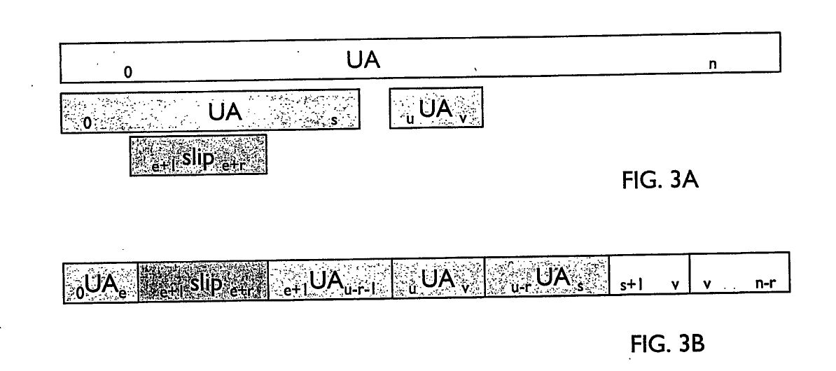

In FIG. 3 an example of a defect management system according to the invention for random writing on a disc is illustrated. As is shown in FIG. 3A there is a large defect on e+1 till e+r. The solution as shown in FIG. 3B is to take the original defect area e+1 till e+r out of the User-Area (UA) and slip u-r till u-r+(v−u) to cross the u . . . v area. This also decreases the free capacity of the UA with a size “r′” which is occupied by the defect.

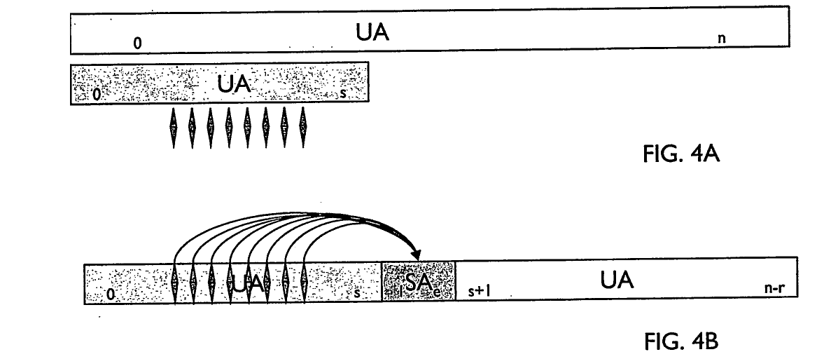

In FIG. 4 an example of a defect management system according to the invention combining linear spare with slipping for streaming is illustrated. As is shown in FIG. 4A there are r single ECC defects. The solution as shown in FIG. 4B is to group the r linear spares in a single block and subsequently slip to make space for the spares. This again decreases the free capacity of the UA with a size “r′” which is occupied by the defect.

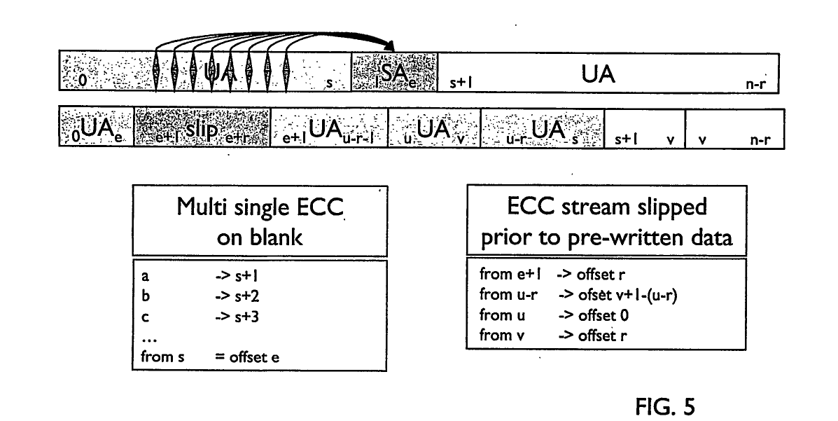

FIG. 5 shows an example of a defect table. According to this example the impact of the invention on known defect tables is limited as it fits the same table structure, only one additional type entry (that is “from-offset”) is required, and the “unusable” and “marked” bit settings can be shared.

1. A method for recording information on a recording medium of the write once type, wherein the method is adapted to enable random recording and random overwriting on said recording medium of the write once type.

2. A method for recording information on a recording medium of the write once type, wherein the method is adapted to perform defect management when recording onto said recording medium of the write once type.

3. A method for recording information on a recording medium of the write once type, wherein the method is adapted to enable undo of previous recording on said recording medium of the write once type.

4. A method for recording information on a recording medium of the write once type, wherein the method is adapted to enable reuse of a previously used recording medium of the write once type.

5. A recording device for recording information on a recording medium of the write once type, said device adapted for carrying out the method according to claim 1, 2, 3, or 4.
